(19) United States
(12) Patent Application Publication
(10) Pub. No.: US 2021/0226085 A1
(43) Pub. Date: Jul. 22, 2021

(54) AREA LIGHT SOURCE AND DISPLAY DEVICE UTILIZING AREA LIGHT SOURCE

(71) Applicant: WUHAN CHINA STAR OPTOELECTRONICS TECHNOLOGY CO., LTD., Wuhan, Hubei (CN)

(72) Inventor: Yong YANG, Wuhan, Hubei (CN)

(21) Appl. No.: 16/631,348

(22) PCT Filed: Feb. 14, 2019
(86) PCT No.: PCT/CN2019/075064

§ 371 Date: Jan. 15, 2020

(30) Foreign Application Priority Data
Oct. 31, 2018 (CN) 201811282292.7

(51) Int. Cl. H01L 33/12; H01L 25/075; H01L 33/62; H01L 33/60

(52) U.S. Cl. CPC H01L 33/12; H01L 33/60; H01L 33/62; H01L 25/0753

(57) ABSTRACT

The present disclosure discloses an area light source and a display device utilizing the area light source. The area light source includes a substrate including a front surface and a back surface both having weld plates and metal wires. First chips are disposed on the front surface of the substrate and welded to the weld plate. Second chips are disposed on the back surface of the substrate and welded tot the weld plate. The area light source and the display device utilizing the area light source adopt double-side in bound improves curve of the substrate during a reflow process, improves short circuit resulted from chip dragging caused by weld paste, and improves the uniformity of the area light source. Even a thickness of the area light source decreases an entire thickness of the area light source and the display device decreases so the display device is thinner.

### FIELD OF INVENTION

The present disclosure relates to fields of display device, more particular, to fields of an area light source and a display device utilizing the area light source.

### BACKGROUND OF INVENTION

Mini light-emitting diode (LED) display technology is competitive in the future organic light-emitting diode (OLED) display technology market. Research of mini LED display devices become popular because mini LED display devices have advantages such as high brightness, flexibility and bendability, high dynamic contrast display, narrow bezels, special-shaped displays, etc. However, for the purpose of implementing flexible display, most substrates adopt flexible circuit boards. Polyimide, a substrate material, causes large internal stress during heating, which makes material of the panel greatly curve after reflow weld processes. As a result, positions of the chips and directions of light emission are affected by the curved material and the subsequent modular assembly process faces a huge challenge. Internal stress is generated when the polyamide materials are in high temperature. The thermal characteristics of the materials are unchangeable thus solution has not been found to solve the internal stress caused by die bond. Double-side display technology mostly adopts edge-light backlights. The display of a back surface of the double-side display also relies on light emission controlled by liquid crystal layers. The structure of double-side display increases the thickness of the display screen and solutions for reducing the thickness of the double-side display have not been found yet.

In the conventional die bond process, internal stress is generated during the process of transferring chips in the die bond machine because die bond processes are only implemented on single-side of substrates. The thinner the substrate is, the higher internal stress is. The internal stress is accumulated and the substrate is curved during the high temperature reflow process, so that weld paste drags chips. Thus, uncompleted welding and short circuiting happens, and the subsequent cutting process is affected.

### Technical Problem

The technical problem that the present disclosure desires to solve is providing an area light source and a display device utilizing the area light source. The area light source adopts double-side die bond to reduce internal stress on a substrate so that curve of panel materials during processes can be improved. When manufacturing double-side area light source for implementing double-side display, displaying of a back surface is implemented by divisional area light source so that thickness of display panel of the display device can be minimized and ultra-thin display panel can be achieved.

### SUMMARY OF INVENTION

To solve the above-mentioned problem, the technical solution is: providing an area light source induces a substrate including a front surface and a back surface. There are weld plates and metal wires on both of the front surface and the back surface. First chips are disposed on the front surface of the substrate and welded to the weld plate. Second chips are disposed on the back surface of the substrate and welded tot the weld plate.

In an embodiment of the present disclosure, a thickness of the substrate ranges from 150 to 200 micrometers

In an embodiment of the present disclosure, the first chips are arranged in array and the dimensions of the first chips are 1 μm-500 μm; the second chips are arranged in array and dimensions of the first chips range from 0.1 mm to 3 mm.

In an embodiment of the present disclosure, a plurality of first light-emitting areas are disposed on the back surface of the substrate, the area light source further includes first driving chips, and each of the first driving chips corresponds to one of the first light-emitting areas.

In an embodiment of the present disclosure, the second chips are red color chips, green color chips, or blue color chips, and each of the first light areas corresponds to one kind of colors of the second chips.

In an embodiment of the present disclosure, in response to a plurality of second light-emitting areas are disposed on the front surface of the substrate, the area light source further includes second driving chips, and each of the second driving chips corresponds to one of the second light-emitting areas; in response to a third light-emitting area disposed on the front surface of the substrate, the area light source further includes a third driving chip, and the third driving chip corresponds to of the third light-emitting area.

In an embodiment of the present disclosure, the area light source further includes a fluorescent film covers the first chips.

In an embodiment of the present disclosure, the substrate further includes a first substrate, an adhere layer disposed of a surface of the first substrate, and a second substrate adhered on the first substrate through the adhere layer.

In an embodiment of the present disclosure, reflection layers are disposed on the front surface of the substrate and the back surface of the substrate, and the reflection layers are disposed between the first chips or disposed between the second chips.

The present disclosure further provides a display device including the area light source and a display device disposed on the area light source and disposed on a side being the same with the first chip.

### Beneficial Effect

The area light source and the display device utilizing the area light source of the present disclosure adopt double-side die bonds. The internal stresses on both side of the substrate should mutually counteract after the die bond process. The internal stress of the substrate adopting double-side die bond is less than the internal stress of the substrate adopting single-side die bond. Therefore, curve of substrate resulted from reflow weld process and short circuit resulted from chip dragging caused by weld paste can be improved. As a result, luminance uniformity of the area light source is improved as well. On the other hand, the substrates adopting double-side die bond are slightly thicker than single-side substrates so that the internal stress of thicker substrate becomes lower during die bond process. The divisional control of light-emitting areas views each of the light-emitting areas as a display pixel in the purpose of displaying simple texts or images. The more the number of the division of the chips is, the more detailed the display resolution is. The back surface of the substrate utilizes the second chip for display. Differ from usual double-side display panel, area light source utilizes three-color (red, green, and blue) chip to directly control display without glass cover, full-size package fluorescence film, or quantum dot film. Although the thickness of the substrate increases, however, the whole thickness of area light source and thickness of the display devices become thinner.

### DESCRIPTION OF THE DRAWINGS

In order to more clearly illustrate the technical solutions in embodiments of the present disclosure, the drawings in the description of the embodiments will be briefly described below. Obviously, the drawings in the following description are only some implementations of the present disclosure. For example, other drawings may be obtained from a skilled person in the art without any creative work.

The present disclosure is further explained below accompanying with the drawings and embodiments.

FIG. 1 illustrates a layer structure of an area light source of the embodiment of the present disclosure.

FIG. 2 illustrates an arrangement of metal wires and weld plates on a front surface of a substrate or a back surface of the substrate of the embodiment of the present disclosure.

FIG. 3 illustrates a layer structure of the substrate of the embodiment of the present disclosure.

FIG. 4 illustrates a corresponding relation between a light-emitting area of the front surface and driving ships of the area light source of the embodiment of the present disclosure.

FIG. 5 illustrates another corresponding relation between the light-emitting area of the front surface and a driving ship of the area light source of the embodiment of the present disclosure.

FIG. 6 illustrates a corresponding relation between a light-emitting area of the back surface and driving ships of the area light source of the embodiment of the present disclosure.

FIG. 7 illustrates a layer structure of a display device of the embodiment of the present disclosure.

Reference number:

| | |
|---|---|
| 1 display device; | |
| 10 area light source; | 20 display panel; |
| 110 substrate; | 120 first chip; |
| 130 second chip; | 140 reflection layer; |
| 150 metal wire; | 160 weld plate; |
| 170 fluorescence film; | 181 first driving chip; |
| 182 second driving chip; | 183 third driving chip; |
| 111 first substrate; | 112 second substrate; |
| 113 adhere layer; | 1101 front surface of the substrate; |
| 1102 back surface of the substrate; | 11011 second light-emitting area; |
| 11012 third light-emitting area; | 11021 first light-emitting area. |

### DETAILED DESCRIPTION OF PREFERRED EMBODIMENTS

The embodiments of the present disclosure are described in detail below, and the examples of the embodiments are illustrated in the drawings. The same or similar reference numbers are used to refer to the same or similar elements or elements having the same or similar functions. The embodiments described below accompanying with the drawings are illustrative and are only used to explain the present disclosure rather than limiting the present disclosure.

The following description of the embodiments is provided to illustrate the specific embodiments of the present disclosure may be implemented. Directional terms mentioned in the present disclosure, such as “upper”, “lower”, “front”, “back”, “left”, “right”, “top”, “bottom”, etc., only refer to relative direction in drawings. Therefore, the directional term is used to describe and understand the present disclosure rather than limiting the present disclosure.

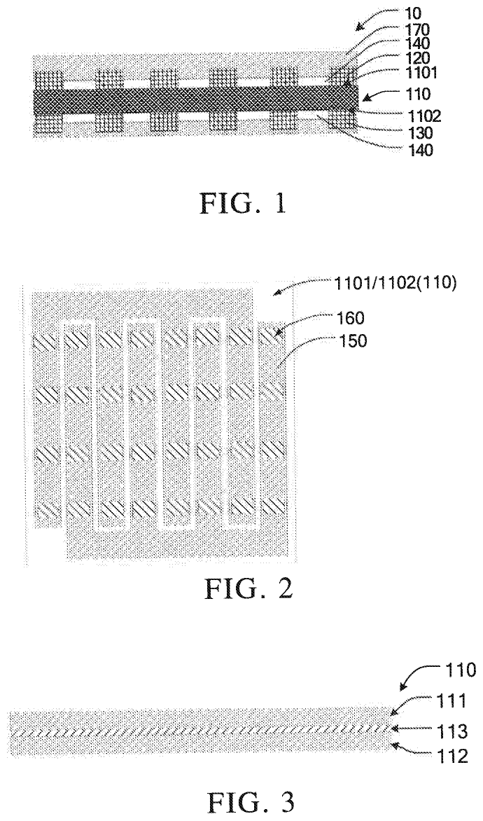

As shown in FIG. 1, in an embodiment, the area light source 10 of the present disclosure includes a substrate 110, a first chip 120, a second chip 130, and a reflection layer 140. The substrate 110 includes a front surface and a back surface. The first chip 120 is disposed on the front surface. The second chip 130 is disposed on the back surface.

As shown in FIG. 2, both of the front surface 1101 and the back surface 1102 includes metal wires 150 and weld plates 160. FIG. 2 is an example of arranging structure of the metal wires 150 and the weld plates 160 of the front surface or the back surface. The first chips 120 are arranged on the front surface 1101 of the substrate and welded to the weld plates 160. The second chips 130 are arranged on the back surface 1102 of the substrate and welded to the weld plates 160.

As shown in FIG. 3, before a die bond operation, manufacturing the substrate 110. In the embodiment, the thickness of the substrate 110 ranges from 150 micrometers to 200 micrometers. The dimension of the substrate 110 is determined according to the size of the display screen. The substrate 110 includes a first substrate 111, a second substrate 112, and an adhere layer 113. The adhere layer 113 is formed by adhering compound glue on the first substrate 111. The substrate 112 is adhered to the first substrate 111 through the adhere layer 113. The front surface 1101 of the substrate is the first substrate 111 which is away from one side of the second substrate 112. The back surface 1102 of the substrate is the second substrate 112 which is away from one side of the first substrate 111.

Please refer to FIG. 1 and FIG. 2. In the die bond operation, the reflective materials are firstly coated on the front surface 1101 of the substrate and the back surface 1102 of the substrate to form the reflection layer 140. The reflection layer 140 covers the metal wires 150 on the substrate 110 in order to increase the refractivity and reflectivity so that luminance of packaged light is improved. The reflective material may be phenol formaldehyde resin, epoxy resin, polyimide resin, polyester resin, white oil, etc. The material used for the reflection layer 140 in this embodiment is white oil. A die bond operation is sequentially performed on the front surface 1101 of the substrate adopts a reflow process. In this embodiment, the first chip 120 is arranged in array on the front surface 1101 of the substrate. The dimension of ach of the first chips 120 is 1 μm-500 μm. There are approximate 20-50 first chips 120 per centimeter squared. Taking a six-inch. screen as an example, the corresponding number of the first chips 120 on the substrate 110 is 2000-5000. After the first chip 120 is disposed, a fluorescence film 170 is overlaid on the first chip 120 to perform color conversion though the fluorescence film 170.

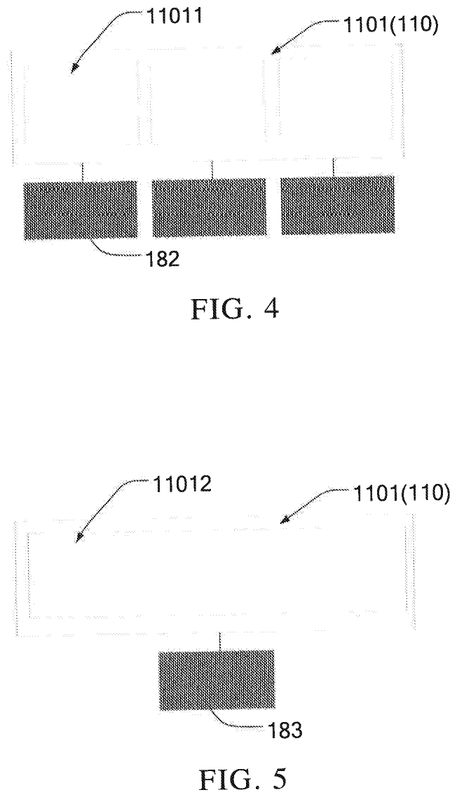

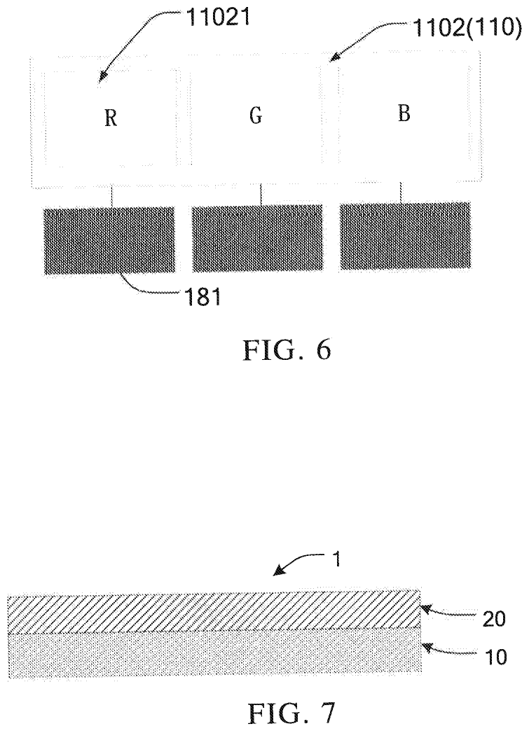

As shown in FIG. 4, in the embodiment, the first chip 120 on the front surface 1101 of the substrate can adopt two driving methods. The first method is dividing the front surface 1101 into a plurality of second light-emitting areas 11011. The area light source 10 of the present disclosure further includes second driving chips 182. Each of the second driving chips 182 corresponds to one of second light-emitting areas 11011. The second method is utilizing a third light-emitting area 11012, which is an entire surface, on the front surface 1101 of the substrate. The area light source 10 further includes a third driving chip 183 corresponding to a third light-emitting area 11012. If the front surface 1101 of the substrate of the embodiment adopts the first method utilizing divisional control of each portion, each of the portions (light-emitting areas) is viewed as one display pixel for display simple texts or images. The resolution of the display quality is improved and becomes more elaborate with increasing number of the chips.

Please refer to FIG. 1 and FIG. 2. A die bond operation is sequentially performed on the back surface 1102 of the substrate adopts a reflow process after finish the formation of the front surface 1101. The first chips 130 are arranged in array on the front surface 1101 of the substrate. The dimension of ach of the second chips 120 is 0.1 mm-3 mm. There are approximate 1-100 second chips 130 per centimeter squared. Taking a six-inch screen as an example, the corresponding number of the second chips 130 on the substrate 110 is 100-10000 according to requirement of resolution. In this embodiment, the second chip 130 is a three basic color (red, green, and blue) chip. The back surface 1102 of the substrate of the present disclosure utilizes the second chip to directly display. In comparison with usual double-side display panel, the area light source 10 of this embodiment utilizes three basic color RGB chip to directly control display. Therefore, no glass cover, no fluorescence film 170 which is entirely packaged on the whole surface, nor quantum dot films are required.

As shown in drawings, the back surface is divided into a plurality of first light-emitting area 11021. The area light source 10 further includes first driving chips 181. Each of the first driving chips 181 corresponds to one of the first light-emitting area 11021. Each of the first light-emitting area 11021 corresponds to one color of the second chip 130. This embodiment adopts divisional control of each portion. Each of the portions (light-emitting areas) is viewed as one display pixel for display simple texts or images. The resolution of the display quality is improved and becomes more elaborate with increasing number of the chips.

The area light source 10 of the present disclosure applies die bond processes on both side of the substrate 110. The internal stresses on both side of the substrate should mutually counteract after the die bond process is completed. The internal stress of the substrate adopting double-side die bond is less than the internal stress of the substrate adopting single-side die bond. Therefore, curve of substrate 110 resulted from reflow weld process and short circuit resulted from chip dragging caused by weld paste can be improved. As a result, luminance uniformity of the area light source is improved as well. On the other hand, the substrates adopting double-side die bond are slightly thicker than single-side substrates so that the internal stress of the thicker substrate 110 becomes lower during die bond process. In this embodiment, the first substrate 111 and the second substrate 112 are adhered to each other to form the thicker substrate 110 through the adhere layer 113.

The present disclosure further provides a display device 1 including the area light source 10 and a display panel 20 on the area light source 10. The display panel 20 is laterally located on one side of the first chip 120. The main design feature of the present disclosure is the structure of the area light source 10. The structure and frame of the display panel 20 will not be repeated.

The display device 1 in this embodiment can achieve double-sided display. The back surface of the display device 1 can directly display by utilizing the second chip 130. In comparison with the conventional double-sided display, the display device 1 in this embodiment directly controls the display by using the RGB chip so that the back surface does not need to be matched with the glass panel. Therefore, an array substrate, and a color film substrate is not required, and the fluorescence film 170 and the quantum dot film which are entirely packaged on the surface are not required. The thickness of the display device 1 is reduced and ultra-thin double-sided display architecture is achieved. Because the back surface of the display device 1 only requires displaying some simple text or images, a local dimming algorithm can be utilized to control the area light source 10 to directly display. The resolution of the display area is related to the number of chips and the number of divisional areas of area light source 10.

The above embodiment is only a preferred embodiment of the present disclosure rather than a limitation of the present disclosure. Any modifications, equivalent substitutions and improvements according to aspects of the present disclosure fall in the protected scope of the present disclosure.

What is claimed is:

1. An area light source, comprising:
a substrate comprising a front surface and a back surface both comprising weld plates and metal wires;
a plurality of first chips arranged to the front surface of the substrate and welded to the weld plates;
a plurality of second chips arranged to the back surface of the substrate and welded to the weld plates.

2. The area light source according to claim 1, wherein a thickness of the substrate ranges from 150 to 200 micrometers.

3. The area light source according to claim 1, wherein the first chips are arranged in an array and dimensions of the first chips are 1 μm-500 μm; the second chips are arranged in an array and dimensions of the first chips range from 0.1 mm to 3 mm.

4. The area light source according to claim 1, wherein a plurality of first light-emitting areas are disposed on the back surface of the substrate, the area light source further comprises first driving chips, and each of the first driving chips corresponds to one of the first light-emitting areas.

5. The area light source according to claim 4, wherein the second chips are red color chips, green color chips, or blue color chips, and each of the first light areas corresponds to one kind of colors of the second chips.

6. The area light source according to claim 1, wherein in response to a plurality of second light-emitting areas are disposed on the front surface of the substrate, the area light source further comprises second driving chips, and each of the second driving chips corresponds to one of the second light-emitting areas; in response to a third light-emitting area disposed on the front surface of the substrate, the area light source further comprises a third driving chip, and the third driving chip corresponds to of the third light-emitting area.

7. The area light source according to claim 1 further comprises a fluorescent film covers the first chips.

8. The area light source according to claim 1, wherein the substrate comprises:
a first substrate;
an adhere layer disposed of a surface of the first substrate;
a second substrate adhered on the first substrate through the adhere layer.

9. The area light source according to claim 1, wherein reflection layers are disposed on the front surface of the substrate and the back surface of the substrate, and the reflection layers are disposed between the first chips or disposed between the second chips.

10. A display device comprising:
the area light source according to claim 1; and
a display panel disposed on the area light source and disposed on a side being the same with the first chips.
